(19) United States
(12) Patent Application Publication
(10) Pub. No.: US 2025/0364510 A1
(43) Pub. Date: Nov. 27, 2025

(54) Package with Functional Chip and with Physically Separate Sense Chip

(71) Applicant: Infineon Technologies Austria AG, Villach (AT)

(72) Inventors: Andrea Francinelli, Villach (AT); Emanuele Bodano, Villach (AT); Gerhard Thomas Nöbauer, Villach (AT); Claus Wächter, Sinzing (DE); Riccardo Pittassi, Villach (AT)

(21) Appl. No.: 19/206,207

(22) Filed: May 13, 2025

(30) Foreign Application Priority Data
May 23, 2024 (DE) 102024204780.5

(51) Int. Cl. H01L 25/16; G01R 31/26; H01L 23/00; H01L 23/495; H01L 23/538; H01L 25/00; H10D 80/30

(52) U.S. Cl. CPC H01L 25/162; G01R 31/2621; H01L 23/49548; H01L 23/538; H01L 24/32; H01L 25/50; H10D 80/30; H01L 24/48; H01L 24/73; H01L 2224/32245; H01L 2224/48257; H01L 2224/73265; H01L 2924/13091

(57) ABSTRACT

A package includes a functional chip configured to provide an electric function involving an electric current, and a sense chip configured to provide an electric sense signal which characterizes the electric current. The functional chip and the sense chip are physically separate chips.

### TECHNICAL FIELD

The present invention relates to a package and to a method of manufacturing a package.

### BACKGROUND

A package, for instance for automotive applications, provides a physical containment for one or more electronic chips comprising one or more integrated circuit elements. Examples of integrated circuit elements of packages are a metal oxide semiconductor field effect transistor (MOSFET), an insulated-gate bipolar transistor (IGBT), and a diode. There is still potentially room to enable package manufacture with relaxed design constraints.

### SUMMARY

There may be a need for a package with relaxed design constraints.

According to an exemplary embodiment, a package is provided which comprises a functional chip configured to provide an electric function involving an electric current, and a sense chip configured to provide an electric sense signal which characterizes said electric current, wherein the functional chip and the sense chip are physically separate chips.

According to another exemplary embodiment, a method of manufacturing a package is provided, wherein the method comprises providing a functional chip configured to provide an electric function involving an electric current, connecting a sense chip with the functional chip and providing said sense chip configured to provide an electric sense signal which characterizes said electric current, and forming the functional chip and the sense chip as physically separate chips.

According to an exemplary embodiment, a package (for example a semiconductor power package) is equipped with a functional chip configured to provide an electric function (for instance an electric switching function). Executing said electric function by the functional chip may involve generation or provision of an electric current, which may have properties of interest. The package may comprise a sense chip configured to provide an electric sense signal (such as an electric current signal). Said electric sense signal may have properties allowing to characterize or obtain information indicative of the afore-mentioned electric current involved in the functionality of the functional chip. Advantageously, the functional chip and the sense chip may be physically separate chips of a common package, i.e. do not form parts of one and the same semiconductor chip or electronic chip component. Providing functional chip and sense chip as separate chips may increase the flexibility of the package design, since there may be less strict or even no constraints of a common integral functional and sense chip. More specifically, the provision of a separate functional chip and a separate sense chip may allow to freely place every constituent of the package as wanted and where wanted in the package. For instance, the provision of one or more separate pins which may be necessary in a common integral functional and sense chip for supporting the sense functionality may be dispensable when providing functional chip and sense chip separately. Moreover, providing functional chip and sense chip as separate dies may allow to advantageously arrange optional further connection elements (such as bond wires) for instance to avoid undesired crossing. Beyond this, the provision of a separate sense chip may make it possible to integrate a just one additional function in the sense chip, for instance in a spare region thereof.

In the following, further exemplary embodiments of the package and the method will be explained.

In the context of the present application, the term “package” may particularly denote a device which may comprise for example two or more chips. For example, at least part of the latter may be mounted on a (in particular partially or entirely electrically conductive) carrier. Said constituents of the package may be optionally encapsulated at least partially by an encapsulant. Furthermore, a connection structure may form part of the package.

In the context of the present application, the term “chip” may in particular denote a semiconductor chip (in particular a power semiconductor chip). The chip may be an active electronic device. In particular, the chip may be a semiconductor chip having at least one integrated circuit element (such as a monolithically integrated transistor) in a surface portion thereof. The chip may be a bare die or may be already packaged or encapsulated. Semiconductor chips implemented according to exemplary embodiments may be formed for example in silicon technology, gallium nitride technology, silicon carbide technology, etc.

In the context of the present application, the term “functional chip” may in particular denote a chip contributing to a main electric function of the package. For example, if the package is a switch package, the functional chip may contribute to the switching functionality. If the package is a processor package, the functional chip may contribute to the processor function, etc.

In the context of the present application, the term “sense chip” may in particular denote a chip which fulfils the function of sensing an electric signal allowing to characterize operation of the functional chip, which may be electrically coupled with the sense chip. For example, the sense chip does not directly contribute to the main electric function of the package. The electric sense signal sensed by the sense chip may be correlated with or may be indicative of the electric current involved in the functionality of the functional chip. More specifically, a sense chip may carry out current sensing for the functional chip (which may be a power MOSFET) to measure or determine a load current of the functional chip. When providing a sense chip separately from a functional chip, the sense chip and the functional chip may be connected so that a current flow splits inversely with respect to resistances of said chips, and a ratio between the electric sense signal of the sense chip (in particular a sense current) and the electric current of the functional chip (such as a source current) may be established. In an embodiment, the sense chip may include one or more sensors measuring the current by a magnetic sense mechanism, like Hall sensors, or GMR (giant magnetoresistance) sensors. In another embodiment, the sense chip may include one or more nonmagnetic sensors.

In the context of the present application, the term “physically separate chips” may in particular denote that functional chip and sense chip may be structurally distinguished bodies (in particular semiconductor bodies) which can be handled independently from each other prior to package manufacture, for instance prior to an encapsulation process. For instance, the functional chip may be a first semiconductor die and the sense chip may be a discrete second semiconductor die.

In the context of the present application, the term “main surface” of a body may particularly denote the largest body surface or one of the largest body surfaces. For instance, a body (such as a chip or a carrier or a clip) may be plate-shaped or substantially plate-shaped and may then have two opposing main surfaces s separated by body material in a thickness direction and connected with each other by a circumferential edge.

In an embodiment, the functional chip and the sense chip have specifications in accordance with the same chip manufacturing technology. Correspondingly, the method may comprise manufacturing the functional chip and the sense chip by the same chip manufacturing technology. Manufacturing functional chip and sense chip by the same chip manufacturing technology may denote that said chips are manufactured by the same processes, with the same characteristics and/or so as to show the same dependencies on parameters such as temperature, electric current and/or electric voltage. To put it shortly, the sense chip may be a physically smaller version of the bigger functional chip with corresponding technological properties. Hence, the sense chip may behave during operation as the functional chip behaves during operation. For example, the same processes may be run for both chips during manufacture. As a result, the functional chip and the sense chip may have the same trench depth, the same pitch, and/or the same implantation. For instance, the sense chip may have a smaller outline but the same interior dimensions and materials as the functional chip. When the functional chip and the sense chip have specifications in accordance with the same chip manufacturing technology, the electric sense signal sensed by the sense chip is a precise and reliable indicator for or fingerprint of the electric current of the functional chip.

For example, at least one integrated circuit element (such as a monolithically integrated transistor, in particular field-effect transistor (FET), more particularly metal oxide semiconductor field-effect transistor (MOSFET)) of the functional chip and at least one integrated circuit element (such as a further monolithically integrated transistor, in particular further field-effect transistor, more particularly further metal oxide semiconductor field-effect transistor) of the sense chip have the same dimensions, have the same pitch and/or have the same implantation properties. A dimension may be a spatial dimension in a length, width and/or depth direction. For instance, such a dimension may be a gate length or a trench depth. A pitch may be a characteristic distance between two adjacent structures of the respective chip or a monolithically integrated circuit element thereof. Implantation properties may relate for example to a chemical element used as a dopant, a dopant concentration and/or a doping process.

In an embodiment, an outline of the functional chip has larger dimensions than an outline of the sense chip. Thus, the exterior dimensions and/or a volume of the functional chip may be larger than the exterior dimensions and/or a volume of the sense chip, respectively. The sense chip may be a physically smaller variant of the functional chip. This may allow to manufacture the package in a compact way. However, the characteristic dimensions of integrated circuit elements (such as a monolithically integrated field-effect transistor) of the sense chip and of the functional chip may be the same. This may ensure that the electric sense signal of the sense chip is characteristic for or indicative of the electric current of the functional chip with high precision. Consequently, using the electric sense signal for controlling or regulating the package (in particular for driving the functional chip) may be justified and reliable.

In an embodiment, a ratio between a main surface area of the functional chip and a main surface area of the sense chip is at least five, for example at least ten. To put it shortly, the main surface of the functional chip may be preferably for example at least half or one order of magnitude larger than the main surface of the sense chip. For example, the main surface of the functional chip may be in a range from 2 mm² to 10 mm² (for example 5 mm²), whereas the main surface of the sense chip may be in a range from 0.2 mm² to 1 mm² (for example 0.5 mm²). This design rules allows the manufacture of the package with low space consumption while nevertheless allowing for a reliable and precise control of the functional chip based on an electric sense signal sensed at the sense chip.

In an embodiment, the package comprises a further functional chip configured to provide a further electric function involving a further electric current and cooperating with the functional chip. The further functional chip may for example provide the same electric function as the afore-mentioned functional chip, for instance an electric switching function. For instance, functional chip and further functional chip may cooperate as low-side switch and high-side switch of a half bridge. The functional chip and the further functional chip may have specifications in accordance with the same chip manufacturing technology, as explained above for the relation between the functional chip and the sense chip. The outline of the functional chip and of the further functional chip may be different or may be the same. For instance, when one of the functional chip and the further functional chip has a longer “on”-percentage during a duty cycle than the other chip, this may be reflected in different physical dimensions of the functional chips.

In an embodiment, the functional chip is a transistor chip and/or a power chip, for example a power transistor chip. In the context of the present application, the term “transistor chip” may in particular denote a chip, such as a semiconductor chip, in which at least a transistor may be integrated, in particular monolithically integrated. Optionally, the chip may comprise at least one further integrated circuit element, such as a diode or a further transistor. In particular, a respective chip with integrated transistor may be a field-effect transistor chip having a source terminal (or pad), a drain terminal (or pad) and a gate terminal (or pad). Alternatively, a respective chip with integrated transistor may be a bipolar transistor chip having an emitter terminal (or pad), a collector terminal (or pad) and a base terminal (or pad). Specific examples of the transistor chips are a metal oxide semiconductor field effect transistor (MOSFET), and an insulated-gate bipolar transistor (IGBT). In the context of the present application, the term “power chip” may in particular denote a chip, such as a semiconductor chip, configured for a power application, for instance a power switching application. In an embodiment, the chip(s) with transistor is/are configured as power semiconductor chips. Thus, a corresponding chip (such as semiconductor chip) may be used for power applications for instance in the automotive field. Corresponding integrated circuit elements may be made for instance in silicon technology or based on wide-bandgap semiconductors (such as silicon carbide, gallium nitride or gallium nitride on silicon). A semiconductor power package may comprise one or more inverter circuits, one or more half bridges, one or more full-bridges, one or more drivers, one or more logic circuits, etc.

In an embodiment, the further functional chip is a further transistor chip and/or a further power chip, for example a further power transistor chip. Preferably, each of the functional chip and the further functional chip may be a semiconductor power transistor chip.

In an embodiment, the functional chip and the further functional chip are connected to form a half bridge. In the context of the present application, the term “half bridge” may particularly denote a circuit composed of an upper transistor switch (“high-side”) and a lower transistor switch (“low-side”). For instance, the transistors may be MOSFETs. The transistors may be connected in a cascode arrangement. The two functional chips may be configured as transistor switches which may be turned on and off complementary to each other (in particular with a non-overlapping dead-time) by applying corresponding voltage waveforms at control terminals (such as gate terminals). A desired result may be an idealized DC-DC conversion scenario, where a square-wave mid voltage level switches between a first electric potential (such as a DC (direct current) bus voltage) and a second electric potential (such as ground). However, other shapes of an output signal may be possible which do not have a square-wave characteristic. The two transistors may be interconnected with a mutual connection of their drain terminals and with a mutual connection of their gate terminals. The mentioned half bridge configuration may be used as such or alone or may be combined with one or more further half bridges (or other electric circuits) to realize a more complex electric function. For instance, two such half bridges may form a full bridge.

In an embodiment, the functional chip and the further functional chip are arranged side-by-side. For example, the functional chip and the further functional chip may be located juxtaposed at the same vertical level.

In an embodiment, the sense chip and the functional chip are stacked on top of each other, for example the sense chip is stacked on top of the functional chip. Corresponding embodiments are shown for instance in FIG. 3, FIG. 4 and FIG. 6. Vertically stacking sense chip and functional chip on top of each other may lead to a very compact package. Furthermore, a stack of sense chip and functional chip may allow to directly connect drain terminals thereof with each other, which may advantageously lead to short electric paths. In an embodiment, the package comprises a controller chip (which may also be denoted as a driver chip) for driving the functional chip and the sense chip and/or for sensing the electric sense signal. Such a controller chip may supply a control signal to a gate terminal of the functional chip and to a gate terminal of the sense chip. Optionally, the controller chip (or another controller chip) may also supply a control signal to a gate terminal of a further functional chip. The controller chip (or another controller chip) may also sense the electric sense signal of the sense chip. The controller chip may process the sensed electric sense signal, for instance for adapting said control signal based on information derived from the electric sense signal characterizing the electric current of the functional chip. Thus, the sensed electric sense signal may be used in terms of a control or regulation loop.

In an embodiment, the controller chip is arranged side-by-side with the sense chip and/or is arranged at another vertical level than the functional chip and/or than the further functional chip. A corresponding embodiment is shown in FIG. 3. While controller chip and sense chip may be arranged juxtaposed at the same vertical level, and functional chip and (if present) further functional chip may be arranged at another common vertical level, controller chip and sense chip may be located preferably above functional chip and further functional chip. This may render the electric interconnections between the various chips simple and efficient. A resulting design of the package may be compact.

In an embodiment, the package comprises an electrically conductive clip arranged between the functional chip and the sense chip. In the context of the present application, the term “clip” may particularly denote a (in particular planar or three-dimensionally curved) plate-type connection element which comprises an electrically conductive material (such as copper) and is an integral body with surface portions or sections to be connected to the functional chip and the sense chip. For instance, such a clip may connect a drain terminal of the functional chip with a drain terminal of the sense chip. It is also possible that said clip connects controller chip and/or further functional chip with functional chip and/or sense chip and/or with each other. The clip may also be connected to a carrier (such as a leadframe structure) on which the functional chip and optionally also the further functional chip may be mounted. For instance, the clip may be connected to a lead section of said carrier.

In an embodiment, the package comprises an at least partially electrically conductive carrier, for example a leadframe structure, carrying the functional chip (and optionally also a further functional chip). In the context of the present application, the term “carrier” may particularly denote a support structure (which may be at least partially electrically conductive) which serves as a mechanical support for the electronic chip(s) to be mounted thereon, and which may also contribute to the electric interconnection between the electronic chip(s) and the periphery of the package. In other words, the carrier may fulfil a mechanical support function and an electric connection function. A carrier may comprise or consist of a single part, multiple parts joined via encapsulation or other package components, or a subassembly of carriers. When the carrier forms part of a leadframe, it may be or may comprise a die pad. More generally, the mentioned carrier may be a leadframe structure (for instance made of copper), a DAB (Direct Aluminum Bonding) substrate, a DCB (Direct Copper Bonding) substrate, etc. Moreover, the carrier may also be configured as Active Metal Brazing (AMB) substrate. In the context of the present application, the term “leadframe” may particularly denote a sheet-like metallic structure which can be bent, punched and/or patterned so as to form leadframe structures as mounting sections for mounting chips, and connection leads for electric connection of the package to an electronic environment. In an embodiment, the leadframe may be a metal plate (in particular made of copper) which may be patterned, for instance by stamping or etching. Forming the chip carrier as a leadframe is a cost-efficient and mechanically as well as electrically highly advantageous configuration in which a low ohmic connection of chips can be combined with a robust support capability of the leadframe. Furthermore, a leadframe may contribute to the thermal conductivity of the package and may remove heat generated during operation of the chip(s) as a result of the high thermal conductivity of the metallic (in particular copper) material of the leadframe.

In an embodiment, a source terminal of the sense chip is electrically decoupled from a source terminal of the functional chip. Thus, electric current or electric signals at the source terminals of a transistor chip-type sense chip and functional chip may be separated, so that said current or signals may be supplied or processed independently from each other.

In an embodiment, a drain terminal of the sense chip is electrically coupled with a drain terminal of the functional chip. Hence, the drain terminals of the sense chip and of the functional chip may be at the same electric potential. For example, this may be accomplished with a short connection path by arranging the functional chip in a flip-chip configuration drain-up and to arrange the sense chip with a drain-down configuration.

In an embodiment, a gate terminal of the sense chip is electrically coupled with a gate terminal of the functional chip. Thus, the gate terminals of the sense chip and of the functional chip may be at the same electric potential. This configuration may allow a controller chip to provide the same control signals to the gate terminals of the functional chip and of the sense chip. This may form a proper basis for obtaining an electric sense signal by the sense chip which is characteristic for the electric current assigned to or provided by the functional chip.

In an embodiment, the functional chip is arranged drain-up and/or the sense chip is arranged drain-down. Such a flip-chip arrangement of the functional chip in combination with an ordinary orientation of the sense chip may lead to an extremely short electrical connection path between the drain terminals of functional chip and sense chip. Electric artefacts (such as loss and/or distortion) may thus be suppressed.

In an embodiment, the package comprises an encapsulant, for example a mold compound, encapsulating at least part of the functional chip and at least part of the sense chip. Hence, a common encapsulation of functional chip and sense chip may be accomplished. Optionally but advantageously, also a controller chip and/or a further functional chip may be at least partially encapsulated in the same encapsulant. In the context of the present application, the term “encapsulant” may particularly denote a material, structure or member surrounding at least part of the chips (and optionally at least part of a carrier) to provide mechanical protection, and optionally electrical insulation and/or a contribution to heat removal during operation. In particular, said encapsulant may be predominantly or even entirely electrically insulating, for instance a mold compound. A mold compound may comprise a matrix of flowable and hardenable material and filler particles embedded therein. For instance, filler particles may be used to adjust the properties of the mold component, in particular to enhance thermal conductivity. As an alternative to a mold compound (for example on the basis of epoxy resin), the encapsulant may also be a potting compound (for instance on the basis of a silicone gel). In still another embodiment, the encapsulant may be a laminate of stacked layers (for instance comprising prepreg and/or resin sheets).

In an embodiment, the sense chip is configured to provide at least one additional function in addition to providing the electric sense signal. By providing the sense chip as a physically separate chip with respect to the functional chip, there may be room for implementing at least one additional function (preferably at least one additional electric function) in a spare area of the sense chip. For example, the at least one additional function may comprise providing a temperature signal indicative of a temperature of the sense chip. For example, a temperature sensor may be integrated (preferably monolithically integrated) in the sense chip for generating said temperature signal. For instance, such a temperature sensor may be embodied as a temperature-sensing resistor. For example, a temperature-sensing resistor may be embodied with four pads connected in Kelvin fashion to enable four-terminal temperature-sensing. Due to the close spatial vicinity of sense chip and functional chip in the same package, preferably encapsulated by the same encapsulant, the temperature information provided by the sense chip may be also indicative of the temperature of the functional chip. Based on the sensed temperature information, control of the functional chip (and optionally also of the sense chip and/or of a further functional chip) by a controller chip may be executed.

However, additionally or alternatively to the temperature sensor, at least one other functional element may be integrated in the sense chip configured to provide at least one additional function. For example, the sense chip may be configured to provide an electric redistribution function in the context of the electronic functionality of the package.

Moreover, by the provision of the sense chip as a physically separate body with respect to the functional chip, a localization and orientation of the sense chip in the package may be selected for avoiding crossing wires (such as bond wires).

In an embodiment, at least one of the functional chip, the sense chip and the further functional chip is configured for operation with a vertical current flow (in particular a current flow perpendicular to a plane within which a carrier and/or a clip extends). Chips being configured for a vertical current flow may have transistor terminals both at an upper main surface and a lower main surface, respectively, of the chip. In particular in such a vertical flow configuration, the package can be formed with extremely short current paths and thus with a quite simple layout.

As substrate or wafer forming the basis of the chip(s), a semiconductor substrate, preferably a silicon substrate, may be used. Alternatively, a silicon oxide or another insulator substrate may be provided. It is also possible to implement a germanium substrate or a III-V-semiconductor material. For instance, exemplary embodiments may be implemented in GaN or SiC technology.

The above and other objects, features and advantages of the present invention will become apparent from the following description and the appended claims, taken in conjunction with the accompanying drawings, in which like parts or elements are denoted by like reference numbers.

### BRIEF DESCRIPTION OF THE DRAWINGS

The accompanying drawings, which are included to provide a further understanding of exemplary embodiments and constitute a part of the specification, illustrate exemplary embodiments.

In the drawings:

FIG. 1 shows a layout of a package according to an exemplary embodiment.

FIG. 2 shows a circuit diagram of a package according to an exemplary embodiment.

FIG. 3 shows three-dimensional views of a package according to an exemplary embodiment with and without an encapsulant.

FIG. 4 shows a cross-sectional view of a package according to an exemplary embodiment.

FIG. 5 shows a cross-sectional view of a package according to another exemplary embodiment.

FIG. 6 shows a cross-sectional view of a package according to still another exemplary embodiment.

### DETAILED DESCRIPTION

The illustration in the drawing is schematically.

Before describing further exemplary embodiments in further detail, some basic considerations will be summarized based on which exemplary embodiments have been developed.

Current sensing power MOSFETs may allow measuring load current in a power conditioning circuit. In particular in multiphase systems, current sensing for current equalizing between different phases may be desired and may be used to provide feedback for a control loop. Current sensing can be obtained by different methods.

A precise and low-loss arrangement is the manufacture of a sensing cell (such as a mirror FET) inside of a power FET. High current power stages may use a system-in-package architecture. An extra connection from the sensing cell inside the power FET to a driver or control chip may be required. In vertical power technology FET applying a flip-chip configuration, the access to the sensing cell may be available on the bottom side of the low-side power FET. As a result, a dedicated exposed pad in the package may be needed.

However, in order to improve cooling, it may be desired to render a power ground area as large as possible as it provides a main heat path. This may be especially critical for smaller package sizes. This may reduce the area for signal connections. For instance, there are footprint specifications where no area for sense FET connections are considered. In such a case, a conventional sense cell architecture with a single die including power FET and sense FET may be inappropriate.

Another approach is to determine an electric current in a low-side transistor by measuring the voltage drop during on-state (which may be denoted as RDS (on)-based current sensing). However, the accuracy of the sensing may be degraded because of the thermal dependency, the gate-source voltage dependency and the process shift.

Summarizing, current sensing in a power chip may still be challenging and may limit the freedom of design.

According to an exemplary embodiment, a package (such as a molded chip package) may comprise a functional chip (for example a power transistor chip) which fulfils an actual electric function of the package. During operation of the functional chip, an electric current may occur which shall be monitored for obtaining information about functional chip operation. In order to accomplish this, the package may be equipped with an additional sense chip (for example a further transistor chip which may be a physically smaller and technologically equal version of the afore-mentioned transistor chip) which may offer a sense functionality by providing an electric sense signal, which may for instance be denoted as electric current sense signal. Descriptively speaking, the electric sense signal may include information and/or may have characteristics or attributes allowing to derive a conclusion about characteristics or attributes of the electric current assigned to or provided by the functional chip. For instance, the sensed information may be used for controlling or regulating operation of the functional chip. Beneficially, the functional chip and the sense chip may be provided as two physically or structurally separate chip bodies rather than as one common shared chip body. This has advantages: When the functional chip and the sense chip are provided as two discrete semiconductor dies, design of the package may be done more flexible by a package designer, since both chips can be configured partially independently from each other. While it may be desired that both the functional chip and the sense chip are formed in accordance with the same chip manufacturing technology for providing comparable electrical characteristics, strict limitations in terms of pin design and the like may be relaxed. More specifically, at least one separate sense pin of a functional chip may not be necessary when providing the functional chip and the sense chip as separate dies.

Hence, an exemplary embodiments may fabricate a sensing device in a separate die, i.e. in a sense chip being physically separate from a functional chip (which may be a power FET). Advantageously, sense chip and functional chip may be manufactured in accordance with the same chip manufacturing technology. This may ensure that the electric sense signal sensed at the sense chip is indicative of or meaningful for the characteristics of the electric current involved in the operation of the functional chip.

In an embodiment, the sense chip may be connected on top of a flipped functional chip (in particular a power FET), such that the chip backsides (in particular drain terminals) are in electrical contact with each other. Said contact may be established by an intermediate conductive layer. The top side of the sense chip may be available for bonding, for instance using bond wires.

In an embodiment, the sense chip may be connected to a gate of the functional chip (such as a power FET). In addition, a connection to a source of the functional chip (in particular power transistor) may be used to create a well-defined potential for a field plate connection in case of a field-plate power transistor with buried source and to have the same reference voltage for the gate drive of the sense chip (in particular a sense FET). All these signals may be already available for connection (for example by wire bonding) in the package.

By that, a package comprising a functional chip and a separate sense chip which may be connected in accordance with a current mirror configuration can be created with an industry-standard footprint. In particular, this can be accomplished using a leadframe without additional exposed pads. Thus, current sensing may be realized in a simple and precise way and with a high degree of flexibility. In particular, there may be no exposed sense pad in the package. This may be combined with the possibility of making use of an industry-standard footprint with a simple leadframe.

Advantageously, exemplary embodiments may allow to use the concept of current sensing based on sense FET mirroring, wherein thermal matching between sense chip and functional chip (such as a power FET) may be possible. Beneficially, functional chip and sense chip may be implemented with the same working conditions (in particular the same gate-source voltage and drain-source voltage). A further advantage is the possibility of a simple trimming at only one temperature to get high matching accuracy.

An exemplary embodiment of the package may be a high current power stage. A corresponding package may for example use a 4 mm×6 mm footprint without exposed pad for current sensing. According to an exemplary embodiment, this may be accomplished with a simple chip embedding package with functional chip(s) and separate sense chip fulfilling the need of highly accurate current sensing matching a standardized footprint. Furthermore, exemplary embodiments may be manufactured with low effort and excellent current sense accuracy.

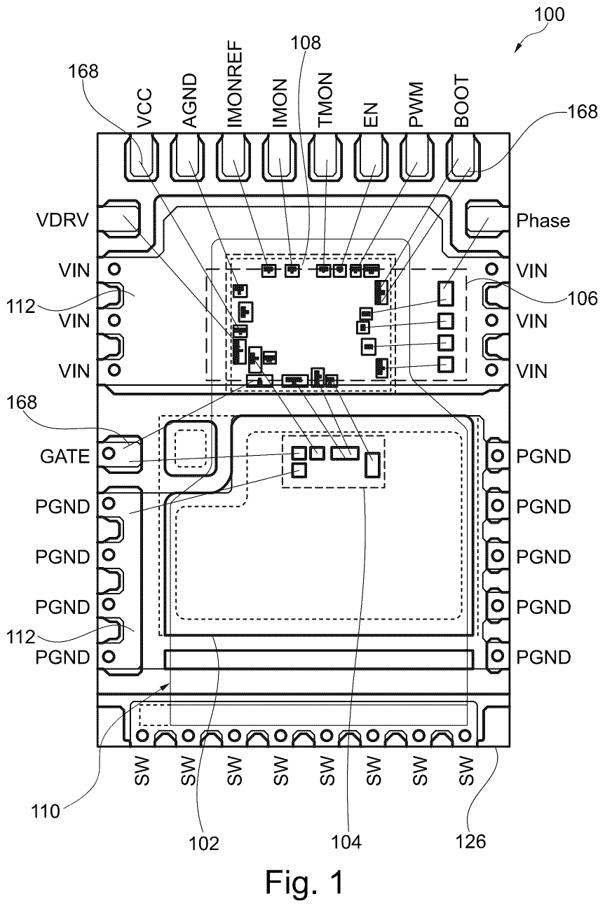

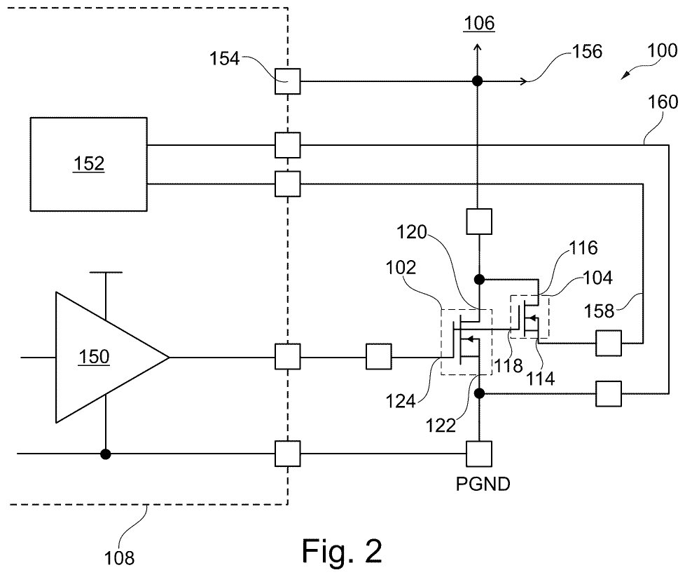

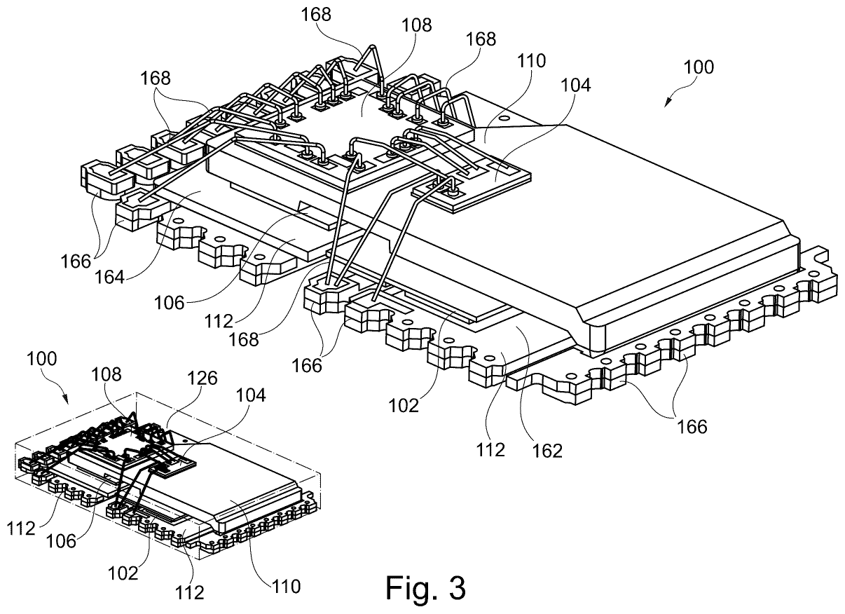

FIG. 1 shows a layout of a package 100 according to an exemplary embodiment. FIG. 2 shows a circuit diagram of the package 100. FIG. 3 shows three-dimensional views of the package 100 with (on a bottom side) and without (on a top side) an encapsulant 126.

Referring to the circuit diagram of FIG. 2, a controller chip 108 comprises a gate driver 150 and a current sense circuit 152. The gate driver 150 is configured to apply a common gate driving signal to a gate terminal 124 of a functional chip 102 and to a gate terminal 118 of a sense chip 104 being physically separate from the functional chip 102. The functional chip 102 may be a low-side power transistor chip of a half bridge. Another constituent of said half bridge is a further functional chip (not shown, but connected at reference sign 106). The further functional chip 106 may be a high-side power transistor chip of the half bridge. However, in addition to the half bridge function, package 100 is also configured as a current sense arrangement. The sense chip 104 is namely configured to provide an electrical sense signal to the current sense circuit 152 of the controller chip 108 which may provide the controller chip 108 with information about the characteristics of an electrical current at the functional chip 102. The gate terminals 118, 124 are electrically coupled with each other. Furthermore, a drain terminal 116 of the sense chip 104 is electrically coupled with a drain terminal 120 of the functional chip 102. The drain terminals 116, 120 are electrically coupled with the further functional chip 106 and with a switch node 154. A tank inductor may also be coupled with the switch node 154 and may be present at reference sign 156. Furthermore, a source terminal 114 of the sense chip 104 may be electrically decoupled from a source terminal 122 of the functional chip 102. By a connection line 158, the sense chip 104 may supply an electric sense signal at its source terminal 114 to the current sense circuit 152 of the controller chip 108. The electric sense signal may be sensed or measured at the source terminal 114 of the sense chip 104. The electric sense signal sensed at sense chip 104 may be a copy or fingerprint of a corresponding electric current generated by the functional chip 102. However, the electric sense signal may be scaled down with respect to said electric current, for instance by a factor of at least 1000. Nevertheless, the electric sense signal may be an indicator for the electric current in the functional chip 102. The controller chip 108 may further process the electric sense signal, for instance for determining signal quality. By a further connection line 160, the functional chip 102 may supply an electric signal at its source terminal 122 to the current sense circuit 152 of the chip controller 108. While the switch node 154 may be at a floating electric potential, the source terminal 122 of the functional chip 102 may be coupled with a fixed electric potential (PGND).

Now turning to the layout of package 100 shown in FIG. 1 and the three-dimensional views of the package 100 of FIG. 3, the package 100 according to the circuit diagram of FIG. 2 will be described in further detail.

As already mentioned, the functional chip 102 is configured to provide an electric function involving an electric current. In the shown embodiment, the electric function of functional chip 102 is that of a low-side MOSFET of a half bridge. More specifically, the functional chip 102 is a first power transistor chip of said half bridge. Functional chip 102 is mounted on a leadframe structure-type carrier 112, which may be a patterned copper plate. For example, functional chip 102 may be mounted on the electrically conductive carrier 112 by an electrically conductive connection medium, such as solder or electrically conductive glue. As shown in FIG. 2, carrier 112 may comprise chip mounting plate sections 162, 164 (for mounting functional chips 102, 106 thereon) and lead sections 166 (to be exposed beyond an encapsulant 126 for enabling electric connection of package 100 with an electronic periphery). Furthermore, a plurality of bond wires 168 is shown for connecting various chip pads with other chip pads or with corresponding lead sections 166. As can be taken from FIG. 1 and FIG. 3, crossing of the bond wires 168 (which may involve a risk for failure during a manufacturing process) may be reliably prevented thanks to the illustrated package design. In particular, this advantageous option is promoted by the separate provision of the sense chip 102, i.e. by providing sense chip 102 separately from the functional chips 102, 106 which relaxes design constraints.

The above-mentioned sense chip 104 is configured to provide an electric sense signal which characterizes said electric current. The sense chip 104 may be a smaller version of the functional chip 102 having a smaller outline and having smaller exterior physical dimensions than the functional chip 102, but being manufactured in accordance with the same chip manufacturing technology as the functional chip 102. As a consequence of same chip manufacturing technology, functional chip 102 and sense chip 104 may be made of the same materials and may have the same characteristic dimensions of their interior monolithically integrated circuit elements, in particular of a monolithically integrated transistor of each of the functional chip 102 and sense chip 104. As can be taken from FIG. 3, sense chip 104 is mounted above functional chip 102 and is physically separated from and electrically coupled with functional chip 102 by an electrically conductive clip 110. For example, sense chip 104 may be mounted on the electrically conductive clip 110 by an electrically conductive connection medium, such as solder or electrically conductive glue. Consequently, an upper main surface portion of functional chip 102 is electrically coupled with a lower main surface portion of sense chip 104.

Advantageously, the functional chip 102 and the sense chip 104 are physically separate chips. Thus, the functional chip 102 and the sense chip 104 are embodied as two separate semiconductor dies rather than as two portions of one common integral semiconductor die. Beneficially, this may make it possible to design functional chip 102 and sense chip 104 separately and individually and to freely place them in the package 100 where appropriate for a desired specification. Contrary to conventional approaches, providing a dedicated pad for current sensing may also be dispensable due to the separate provision of functional chip 102 and sense chip 104.

As already mentioned, the functional chip 102 and the sense chip 104 may have specifications in accordance with the same chip manufacturing technology. More specifically, a monolithically integrated field-effect transistor of the functional chip 102 and a monolithically integrated field-effect transistor of the sense chip 104 may have the same dimensions, the same pitch and the same implantation properties. However, as can be taken from FIG. 1 and FIG. 3, an outline of the functional chip 102 may have larger dimensions than an outline of the sense chip 104. As a rule of thumb, an upper main surface of the functional chip 102 may be for example about one order of magnitude larger than an upper main surface of the sense chip 104. To put it shortly, sense chip 104 may be a physically smaller version of functional chip 102 while both chips 102, 104 may be preferably manufactured in accordance with the same chip manufacturing technology.

As already mentioned in the context of the description of FIG. 2, package 100 may comprise further functional chip 106 configured to provide a further electric function involving a further electric current and cooperating with the functional chip 102. The sense chip 104 (or another sense chip, not shown) may be configured to provide an electric sense signal which characterizes said further electric current. In the shown embodiment, the electric function of further functional chip 106 is that of a high-side MOSFET of the half bridge formed together with functional chip 102. Hence, the further functional chip 106 is a further power transistor chip. Also the further functional chip 106 is mounted on the leadframe structure-type carrier 112, side-by-side with and at the same vertical level as functional chip 102. For example, the further functional chip 106 may be mounted on the electrically conductive carrier 112 by an electrically conductive connection medium, such as solder or electrically conductive glue.

For example, the functional chip 102 and the further functional chip 106 may have specifications in accordance with the same chip manufacturing technology. More specifically, the monolithically integrated field-effect transistor of the functional chip 102 and a monolithically integrated field-effect transistor of the further functional chip 106 may have the same dimensions, the same pitch and the same implantation properties. However, as can be taken from FIG. 1 and FIG. 3, an outline of the functional chip 102 may have larger dimensions than an outline of the further functional chip 106. Alternatively, an outline of the functional chip 102 may have the same or even smaller dimensions than the outline of the further functional chip 106. This sizing can be adjusted in accordance with operation characteristics of functional chips 102, 106, for example in accordance with different or identical “on”-times of functional chips 102, 106 during operation of the package 100.

FIG. 1 and FIG. 3 also show the controller chip 108 for driving the functional chip 102 and the sense chip 104, for sensing the electric sense signal from the sense chip 104 and optionally for sensing a signal from the functional chip 102. Although not shown, it is optionally possible that the controller chip 108 (or alternatively another controller chip) also drives the further functional chip 106.

As can be taken best from FIG. 3, the controller chip 108 is arranged side-by-side with and at the same vertical level as the sense chip 104. Also the controller chip 108 may be mounted on top of the clip 110. For example, controller chip 108 may be mounted on the electrically conductive clip 110 by an electrically conductive connection medium, such as solder or electrically conductive glue. In a further example, the controller chip 108 may be mounted on the electrically conductive clip 110 by an electrically insulating connection medium, such as electrically insulating glue. Furthermore, the controller chip 108 is arranged at another vertical level than, i.e. above of, the functional chip 102 and the further functional chip 106. The shown chip configuration of FIG. 3 is highly compact.

As illustrated on the bottom side of FIG. 3, an encapsulant 126, here embodied as a mold compound, encapsulates the functional chip 102, the further functional chip 106, the sense chip 104, the controller chip 108, the clip 110 and part of the carrier 112. However, another part of the carrier 112 may be exposed beyond the encapsulant 126 for enabling to establish an electric and/or a thermal connection of the encapsulated package 100 with an electronic environment (for instance a mounting base such as a printed circuit board, PCB) and/or for heat removal. To establish said electric connection, electrically conductive lead sections 166 of carrier 112 may be exposed beyond the encapsulant 126. For instance, said exposed lead sections 166 may be connected in an electrically conductive way with a mounting base (such as a PCB, not shown) on which the package 100 may be mounted. When exposing a plate section of carrier 112 beyond the encapsulant 126, such an exposed plate section may be used for dissipating heat generated by the encapsulated chips during operation of the package 100 and/or may be connected with a heat sink (not shown).

Advantageously, the sense chip 104 may be configured to provide at least one additional function in addition to providing the electric sense signal. In the described embodiment, the sense chip 104 may be equipped with a temperature sensor so that the sense chip 104 may provide a temperature signal indicative of its temperature to the controller chip 108. The integration of an additional function in the sense chip 104 is possible due to the fact that the sense chip 104 is provided as a separate semiconductor die with regard to the functional chips 102, 106.

Although the package-type of FIG. 2 and FIG. 3 is that of a QFN (quad-flat no-lead package) power stage with sense integrated circuit, the functionality described referring to FIG. 1 to FIG. 3 can also be provided with other types of packages.

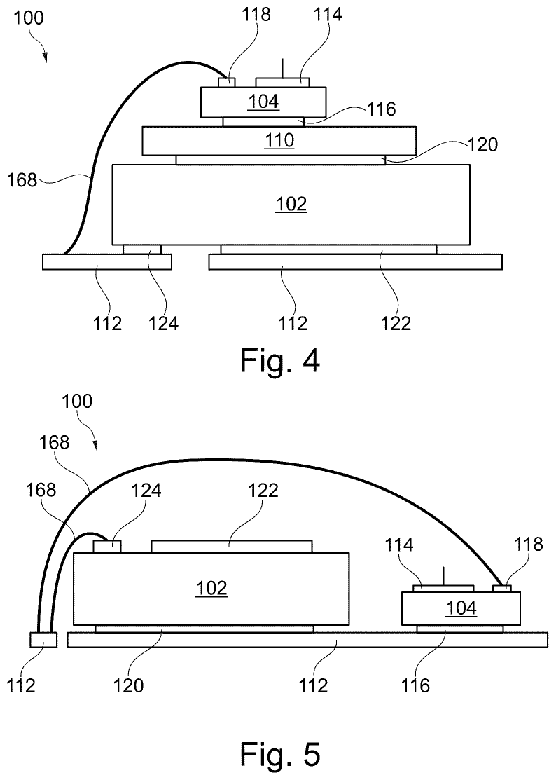

FIG. 4 shows a cross-sectional view of a package 100 according to an exemplary embodiment.

In the package 100 according to FIG. 4, only a single functional chip 102 is foreseen. Said functional chip 102 is vertically stacked with a smaller but preferably technologically equal sense chip 104 arranged above the functional chip 102. A clip 110, such as a copper plate structure, is sandwiched between the bottom-sided functional chip 102 and the top-sided sense chip 104. The bottom side of the functional chip 102 is mounted on a carrier 112, such as a leadframe structure.

The functional chip 102 may be a field-effect transistor power chip experiencing vertical current flow during operation and being arranged in a flip-chip configuration. Thus, a drain terminal 120 of the functional chip 102 is arranged on an upper main surface of the functional chip 102, whereas a source terminal 122 and a gate terminal 124 of the functional chip 102 are arranged on a bottom main surface thereof and are connected with the carrier 112 in an electrically conductive fashion.

The sense chip 104 may also be a field-effect transistor chip experiencing vertical current flow during operation and being a smaller but preferably technologically equivalent version of the functional chip 102. A drain terminal 116 of the sense chip 104 is arranged on a lower main surface of the sense chip 104, whereas a source terminal 114 and a gate terminal 118 of the sense chip 104 are arranged on an upper main surface thereof.

As shown, the source terminal 114 of the sense chip 104 is electrically decoupled from the source terminal 122 of the functional chip 102. However, the drain terminal 116 of the sense chip 104 is electrically coupled with the drain terminal 120 of the functional chip 102 by the clip 110. Moreover, the gate terminal 118 of the sense chip 104 is electrically coupled with the gate terminal 124 of the functional chip 102 by a bond wire 168.

A skilled person will understand that clip 110 and bond wires 168 implemented in the embodiments shown in the figures are only examples for electrically conductive connection structures. They may be substituted by other electrically conductive connection structures. For instance, bond wires or bond ribbons may be used instead of a clip, or vice versa, in each and every embodiment described herein. Additionally or alternatively to such electrically conductive connection structures, also carrier 112 may fulfil a corresponding function.

FIG. 5 shows a cross-sectional view of a package 100 according to another exemplary embodiment.

The embodiment of FIG. 5 differs from the embodiment of FIG. 4 in particular in that, according to FIG. 5, the functional chip 102 and the sense chip 104 are arranged side-by-side rather than being vertically stacked according to FIG. 4.

Drain terminal 116 and drain terminal 120 are electrically coupled with each other by being both mounted on carrier 112. Gate terminal 118 and gate terminal 124 are electrically coupled with each other by both being connected to the carrier 112 by a respective bond wire 168. Source terminal 114 and source terminal 122 are decoupled from each other.

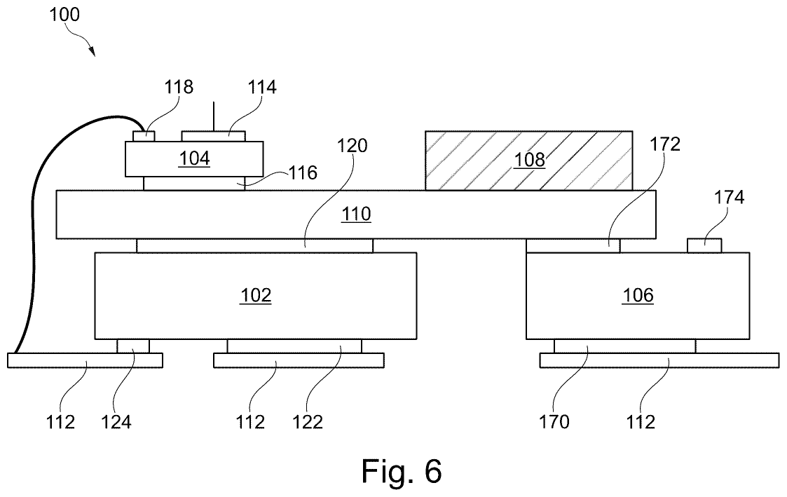

FIG. 6 shows a cross-sectional view of a package 100 according to still another exemplary embodiment.

The embodiment of FIG. 6 differs from the embodiment of FIG. 4 in particular in that, according to FIG. 6, a further functional chip 106 and a controller chip 108 are additionally foreseen. The further functional chip 106 is arranged side-by-side with the functional chip 102 and has a drain terminal 170 being mounted on the carrier 112. A source terminal 172 of the further functional chip 106 is connected to a bottom side of clip 110. A gate terminal 174 of the further functional chip 106 is arranged on the same main surface of the further functional chip 106 as its source terminal 172. Moreover, the controller chip 108 is mounted side-by-side with the sense chip 104 on the upper main surface of the clip 110.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A package, comprising:
a functional chip configured to provide an electric function involving an electric current; and
a sense chip configured to provide an electric sense signal which characterizes the electric current,
wherein the functional chip and the sense chip are physically separate chips.

2. The package of claim 1, wherein the functional chip and the sense chip have specifications in accordance with a same chip manufacturing technology.

3. The package of claim 1, wherein at least one integrated circuit element of the functional chip and at least one integrated circuit element of the sense chip have same dimensions, have a same pitch, and/or have same implantation properties.

4. The package of claim 1, wherein an outline of the functional chip has larger dimensions than an outline of the sense chip.

5. The package of claim 1, wherein a ratio between a main surface area of the functional chip and a main surface area of the sense chip is at least five.

6. The package of claim 1, wherein the functional chip is a transistor chip and/or a power chip.

7. The package of claim 1, further comprising:
a further functional chip configured to provide a further electric function involving a further electric current and cooperating with the functional chip.

8. The package of claim 7, wherein the functional chip is a transistor chip and/or a power chip, and wherein the further functional chip is a further transistor chip and/or a further power chip.

9. The package of claim 7, wherein the functional chip and the further functional chip are connected to form a half bridge.

10. The package of claim 7, wherein the functional chip and the further functional chip are arranged side-by-side.

11. The package of claim 1, wherein the sense chip and the functional chip are stacked on top of each other.

12. The package of claim 1, further comprising:
a controller chip configured to drive the functional chip and the sense chip and/or to sense the electric sense signal.

13. The package of claim 12, wherein the controller chip is arranged side-by-side with the sense chip and/or is arranged at another vertical level than the functional chip.

14. The package of claim 1, further comprising:
an electrically conductive clip arranged between the functional chip and the sense chip.

15. The package of claim 1, further comprising:
an at least partially electrically conductive carrier carrying the functional chip.

16. The package of claim 1, wherein:
a source terminal of the sense chip is electrically decoupled from a source terminal of the functional chip; and/or
a drain terminal of the sense chip is electrically coupled with a drain terminal of the functional chip; and/or
a gate terminal of the sense chip is electrically coupled with a gate terminal of the functional chip; and/or
the functional chip is arranged drain-up and/or the sense chip is arranged drain-down.

17. The package of claim 1, further comprising:
an encapsulant encapsulating at least part of the functional chip and at least part of the sense chip.

18. The package of claim 1, wherein the sense chip is configured to provide at least one additional function in addition to the electric sense signal.

19. A method of manufacturing a package, the method comprising:
providing a functional chip configured to provide an electric function involving an electric current;
connecting a sense chip with the functional chip, the sense chip configured to provide an electric sense signal which characterizes the electric current; and
forming the functional chip and the sense chip as physically separate chips.

20. The method of claim 19, wherein forming the functional chip and the sense chip as physically separate chips comprises manufacturing the functional chip and the sense chip by a same chip manufacturing technology.
